(19) United States
(12) Patent Application Publication
(10) Pub. No.: US 2025/0113568 A1
(43) Pub. Date: Apr. 3, 2025

(54) SILICON CARBIDE CHANNEL WITH CAPPING SEMICONDUCTOR HAVING HIGHER CHARGE CARRIER MOBILITY

(71) Applicant: GlobalFoundries U.S. Inc., Malta, NY (US)

(72) Inventor: William J. Taylor, JR., Clifton Park, NY (US)

(21) Appl. No.: 18/478,452

(22) Filed: Sep. 29, 2023

(51) Int. Cl. H01L 29/10; H01L 29/08; H01L 29/16; H01L 29/66; H01L 29/808

(52) U.S. Cl. CPC H10D 62/328; H10D 12/031; H10D 30/831; H10D 62/149; H10D 62/8325

(57) ABSTRACT

The disclosure provides a structure including a silicon carbide (SiC) channel horizontally between a source and a drain drift region. The SiC channel has opposite doping from the source and the drain drift region. A capping semiconductor is on the SiC channel and is horizontally between the source and the drain drift region. The capping semiconductor includes a semiconductor having a higher charge carrier mobility than the SiC channel. A gate structure is on the capping semiconductor.

### BACKGROUND

Silicon carbide (SiC), also known as “carborundum,” is a material of growing interest for devices configured to operate at high temperatures and/or high voltages. Semiconductor substrates formed of SiC can be used to form many types of devices, including field effect transistors (FETs). In conventional SiC-based FET structures, electrical resistance within the channel region may negatively affect device performance. As compared to other substrate materials, SiC-based substrates may have lower charge carrier mobility and/or a greater number of material defects along the interface(s) between SiC and other materials. Conventional SiC-based devices may undergo further doping or counterdoping to compensate for lower charge carrier mobility and/or surface treatments to reduce defects, but neither approach on its own will fully compensate for these underlying challenges.

### SUMMARY

The illustrative aspects of the present disclosure are designed to solve the problems herein described and/or other problems not discussed.

Embodiments of the disclosure provide a structure including: a silicon carbide (SiC) channel horizontally between a source and a drain drift region, wherein the SiC channel has opposite doping from the source and the drain drift region; and a capping semiconductor on the SiC channel and horizontally between the source and the drain drift region, wherein the capping semiconductor includes a semiconductor having a higher charge carrier mobility than the SiC channel, and a gate structure is on the capping semiconductor.

Further embodiments of the disclosure provide a structure including: a silicon carbide (SiC) substrate including: a drain drift region having a first doping type and included within a vertical junction field effect transistor (JFET), a first channel having a second doping type and horizontally adjacent a first end of the drain drift region, and a first source having the first doping type and horizontally adjacent the first channel, wherein the first channel is horizontally between the drain drift region and the first source, a gate structure over the first channel of the SiC substrate; and a capping semiconductor on the first channel and horizontally between the first source and the drain drift region, wherein the capping semiconductor includes a semiconductor having a higher charge carrier mobility than SiC, and the capping semiconductor is vertically interposed between the first channel and the gate structure.

Additional embodiments of the disclosure provide a method including: forming a silicon carbide (SiC) substrate including a channel horizontally between a source and a drain drift region, wherein the channel has opposite doping from the source and the drain drift region; and forming a capping semiconductor on the SiC channel and horizontally between the source and the drain drift region, wherein the capping semiconductor includes a semiconductor having a higher charge carrier mobility than the SiC channel.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 depicts a cross-sectional view of a structure according to embodiments of the disclosure.

FIG. 2 depicts an expanded cross sectional view of a channel and capping semiconductor between a source and drain according to embodiments of the disclosure.

FIG. 3 depicts a cross-sectional view of a field effect transistor over a vertical junction field effect transistor (JFET) according to embodiments of the disclosure.

FIGS. 4-8 depict processes of a method to form a silicon carbide channel and capping semiconductor according to embodiments of the structure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

As compared to other substrate materials, SiC-based substrates may have lower charge carrier mobility and/or a greater number of material defects along the interface(s) between SiC and other materials. Conventional SiC-based devices may undergo further doping or counterdoping to compensate for lower charge carrier mobility and/or surface treatments to reduce defects, but neither approach on its own will fully compensate for these underlying challenges. The disclosure provides a structure including a silicon carbide (SiC) channel horizontally between a source and a drain. The SiC channel has opposite doping from the source and the drain. A capping semiconductor is on the SiC channel and horizontally between the source and the drain. The capping semiconductor includes a semiconductor having a higher charge carrier mobility than the SiC channel. A gate structure is on the capping semiconductor. During operation, the capping semiconductor may provide a lower resistance electrical pathway from source to drain, while preserving SiC conductive pathways below the drain for other components (e.g., a vertically extending junction field effect transistor (JFET)).

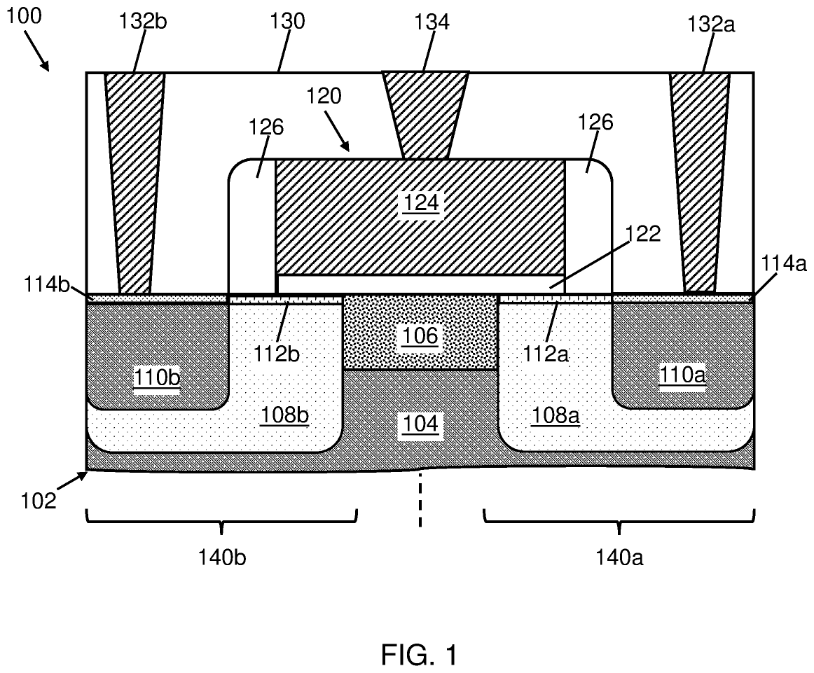

Referring to FIG. 1, embodiments of the disclosure provide a structure 100 (alternatively an integrated circuit (IC) structure) capable of being processed to form an IC structure according to embodiments of the disclosure. Structure 100 may be formed on a silicon carbide (SiC) substrate 102, which may be in the form of a bulk wafer or other layer of SiC material. SiC substrate 102 may not be entirely composed of SiC, i.e., it may include various dopants and/or other materials for affecting its conductivity. The SiC material within SiC substrate 102 may have notably different properties from other types of semiconductor substrates, including those of crystalline or amorphous silicon (Si). During operation, integrated circuits incorporating SiC materials may offer a much higher (i.e., ten times or more) breakdown electric field strength and higher (i.e., three times or more) band gap, both of which offer a wider range of conductivity control through doping of the SiC material. These operational advantages may come with certain technical limitations, e.g., higher amounts of electrical resistance when the SiC material is subject to electrical biasing. Embodiments of the disclosure mitigate or overcome such limitations by providing active semiconductor materials with varying compositions.

Portions of SiC substrate 102 may be doped to a desired polarity and concentration. For instance, SiC substrate 102 may include a lightly doped lower electron drift region (simply “lower drift region” hereafter) 104 with N-type doping. Doping is the process of introducing impurities (dopants) into the semiconductor substrate, or elements formed on the semiconductor substrate, and is often performed with a mask (or previously-formed, elements in place) so that only certain areas of the substrate will be doped. A “dopant” refers to an element introduced into a semiconductor to establish either P-type (acceptors) or N-type (donors) conductivity. Dopants are of two types: “donors” and “acceptors.” N type implants are donors and P type are acceptors. In the case of a silicon substrate, common dopants may include, e.g., boron (B), and/or indium (In), for P-type doping. For N-type doping, the doped element(s) may include, for example, phosphorous (P) arsenic (As), and/or antimony (Sb). P-type and N-type doping types may be further characterized by their doping intensity relative to a baseline doping concentration for the material. P-type doped materials with an elevated number of “holes,” i.e., charge carriers having a positive charge, are classified as being P+ doped. P-type doped materials carrying a greatly diminished number of electrons are classified as being P− doped. N-type doped materials with an elevated number of electrons are classified as being N+ doped. N-type doped materials carrying a greatly diminished number of holes are classified as being N− doped.

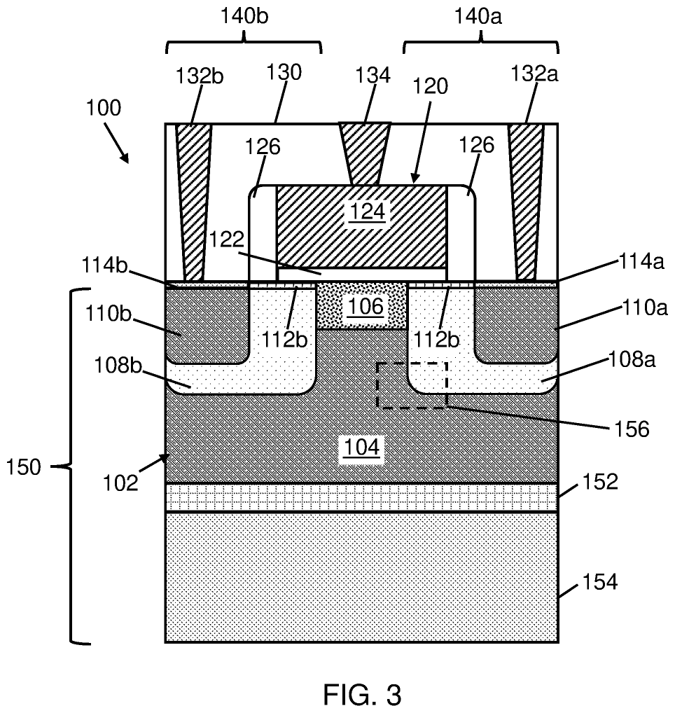

As noted herein, portions of SiC substrate 102 may be doped to provide lower drift region 104. A drift region refers to a semiconductive region with a low enough doping concentration to prevent electrons from flowing therethrough, except under application of a sufficient biasing voltage. Lower drift region 104 in structure 100 may be the layer on which planar transistor components are formed, and as discussed elsewhere herein may be structurally integrated into a junction field effect transistor (JFET) to assist in supplying power through another field effect transistor (FET) formed thereon. Lower drift region 104 may be on other layers of material (e.g., buffer region 152 (FIG. 3) and drain terminal 154 (FIG. 3) discussed herein), but these layers are omitted from FIG. 1 solely to better illustrate the material(s) formed on lower drift region 104. A dashed line in FIG. 1 indicates where materials of structure 100 below lower drift region 104 are located.

Structure 100 may include a drain drift region 106 over lower drift region 104. Drift regions 104, 106 together may define part of one drift region for a JFET but may have different amounts of doping. Lower drift region 104 and drain drift region 106 may include SiC, and may have the same doping type (e.g., n-type doping) but drain drift region 106 may have a significantly higher concentration of dopants therein. Specifically, the doping concentration of drain drift region 106 may be sufficiently high to provide a conductive region even without a voltage being applied thereto. Thus, drift regions 104, 106 provide a graded doping profile within SiC substrate 102. Drain drift region 106 may be free of non-SiC materials, i.e., it may not include a significant amount of electrically detectable crystalline or amorphous silicon (Si) atoms that are not bonded to carbon. During operation, drain drift region 106 may electrically couple a MOSFET transistor over lower drift region 104 to the electrically active material(s) within lower drift region 104.

SiC substrate 102 includes at least one SiC channel 108 horizontally adjacent drain drift region 106. Structure 100 may include multiple SiC channels 108, e.g., as shown in FIG. 1. In this case, structure 100 includes a first SiC channel 108a and a second SiC channel 108b on opposite horizontal ends of drain drift region 106. SiC channel(s) 108, similar to lower drift region 104 and drain drift region 106, may be substantially free of crystalline or amorphous Si. To define part of a MOSFET structure, SiC channel(s) 108 may be doped to have the opposite polarity from drain drift region 106, i.e., SiC channel(s) 108 may have P-type doping in the case where drain drift region 106 is doped N-type or vice versa.

To provide the third active terminal of a MOSFET, SiC substrate 102 also includes at least one source 110 adjacent to a respective SiC channel 108. Thus, structure 100 may include a first source 110a adjacent first SiC channel 108a and a second source 110b adjacent second SiC channel 108b. Source(s) 110a, 110b may have the same doping type as drain drift region 106 and the opposite doping type from SiC channel(s) 108a, 108b. That is, source(s) 110a, 110b may be doped N-type where SiC channel(s) 108a, 108b are doped P-type or vice versa. In some cases, source(s) 110a, 110b may have a higher doping concentration than drain drift region 106, e.g., source(s) 110a, 110b may have “N+” doping but drain drift region 106 may have “N−” doping. Each SiC channel 108a, 108b may be horizontally adjacent drain drift region 106 at one horizontal end and a respective source 110a, 110b at an opposite horizontal end.

By applying a threshold voltage to SiC channel(s) 108a, 108b through an overlying gate structure 120, the conductivity between drain drift region 106 and source(s) 110a, 110b is electrically controllable. Embodiments of the disclosure provide a capping semiconductor 112 on SiC channel(s) 108a, 108b to provide stronger control of electrical conductivity between drain drift region 106 and source(s) 110a, 110b while retaining the benefits of SiC material(s) within drain drift region 106, SiC channel(s) 108a, 108b, and source(s) 110a, 110b. In the case where two SiC channels 108a, 108b are included in structure 100, a first capping semiconductor 112a may be on SiC channel 108a and a second capping semiconductor 112b may be on SiC channel 108b. Capping semiconductor(s) 112 each may be on an upper surface of SiC channel 108. Capping semiconductor(s) 112 may include any currently known or later developed semiconductor having a higher charge carrier mobility than the composition of SiC channel(s) 108a, 108b. According to an example, capping semiconductor(s) 112 may include crystalline silicon (e.g., formed by epitaxial growth) and may have a vertical thickness of at most approximately ten nanometers (nm). The vertical thickness of capping semiconductor(s) 112 may be significantly less than that of SiC channel(s) 108. Gate structure 120 may be located vertically over capping semiconductor(s) 112, and thus may be vertically interposed between SiC channel(s) 108 and gate structure 120.

Optionally, each source 110 also may include a source capping semiconductor 114, e.g., a first source capping semiconductor 114a on first source 110a and a second source capping semiconductor 114b on second source 110b. Each source capping semiconductor 114, similar to capping semiconductor 112, may be substantially free of SiC and thus may include crystalline Si and/or other semiconductors having a greater charge carrier mobility than SiC. Source capping semiconductor(s) 114 may have the same vertical thickness or a similar vertical thickness to capping semiconductor(s) 112, e.g., capping semiconductor(s) 114 may be at most approximately ten nm thick. Source capping semiconductor(s) 114 may be distinguishable from capping semiconductor(s) 112 by having an opposite doping type, e.g., they may be doped N-type in the case where capping semiconductor(s) 112 are doped P-type and vice versa. Capping semiconductor(s) 114 may be on source(s) 110, e.g., to similarly improve charge mobility from source(s) 110 to SiC channel(s) 112 significantly decreasing the electrical resistance through these active semiconductor regions. In any case, capping semiconductor(s) 112, 114 may not be in drain drift region 106, and drain drift region 106 moreover may be free of any capping semiconductor(s) thereon. An upper surface of drain drift region 106 may interface directly with a lower surface of gate structure 120.

Gate structure 120 includes multiple components for electrical biasing of SiC channel(s) 108 thereunder. According to an example, one gate structure 120 may affect multiple FET structures by biasing multiple SiC channels 108 (e.g., first SiC channel 108a and second SiC channel 108 simultaneously). Gate structure 120 may be a metal or polysilicon gate and may include one or more conductive components for providing a gate terminal for a MOSFET. For example, Gate structure 120 may include a high dielectric constant (high-K) gate dielectric layer 122 and a gate conductor 124 thereover. Gate dielectric layer 122 may include insulators such as hafnium silicate (HfSiO), hafnium oxide (HfO₂), zirconium silicate (ZrSiOₓ), zirconium oxide (ZrO₂), silicon oxide (SiO₂), silicon nitride (Si₃N₄), silicon oxynitride (SiON), high-k material (i.e., any material having a dielectric constant of more than 3.9) or any combination of these materials. Gate conductor 124 may include polysilicon and/or metal layers, and in some cases may include a combination of materials such as work function metal layer(s) and gate conductor(s) (only one type of cross hatching is shown for ease of illustration). A gate cap (not shown) may also be formed over gate structure 120.

Gate structure 120 also may include one or more spacers 126, e.g., two spacers 126 are shown adjacent opposing sidewalls of gate dielectric layer 122 and gate conductor 124. Spacers 126 may be provided as one or more bodies of insulating material formed above SiC substrate 102 by deposition/etching, thermal growth, etc. Spacer(s) 126 may include one or more low-K dielectric materials, i.e., dielectric materials with a dielectric constant of at most approximately 3.9. Spacer(s) 126, for example, may include one or more insulative oxide and/or nitride materials.

Structure 100 also may include an inter-layer dielectric layer (ILD) 130 over SiC substrate 102 and gate structure 120 to a desired height. ILD 130 may include one or more low-k dielectric materials currently known or later developed for vertical electrical separation in middle of line (MOL) processing. For instance, ILD 130 may include one or more of silicon nitride (Si₃N₄), silicon oxide (SiO₂), fluorinated SiO₂ (FSG), hydrogenated silicon oxycarbide (SiCOH), etc. The upper surface of ILD 130 may be substantially planar (e.g., by implementation of chemical mechanical planarization (CMP)).

Structure 100 may include various electrically conductive materials within ILD 130 to connect certain electrically active material(s) to metal wiring above ILD 130. A set of source/drain (S/D) contacts 132 within ILD 130 may be coupled to source(s) 110, e.g., a first S/D contact 132a is over first source 110a and a second S/D contact 132 is over second source 110b. ILD 130 may not include any contacts to drain drift region 106, e.g., because drain drift region 106 may be coupled to and/or define part of a JFET structure with separate electrical pathways as discussed herein. A gate contact 134 within ILD 130 may be on gate conductor(s) 124. Contact(s) 132a, 132b, 134 may include any currently known or later developed conductive materials (e.g., copper (Cu), aluminum (Al), tungsten (W), etc. within the removed portion(s) of ILD 130. Thereafter, ILD 130, contact(s) 132a, 132b, 134 may be planarized (e.g., by CMP) such that the upper surfaces of these elements are substantially coplanar with each other. In structure 100, drain drift region 106 may be included within two different FETs, i.e., a first MOSFET 140a and a second MOSFET 140b. First MOSFET 140a may include first SiC channel 108a horizontally between drain drift region 106 and first source 110a. In first MOSFET 140a, first capping semiconductor 112a may be over first SiC channel 108a and beneath gate structure 120. Second MOSFET 140b may include second SiC channel 108b horizontally between drain drift region 106 and second source 110b. In second MOSFET 140b, second capping semiconductor 112b may be over second SiC channel 108b and beneath gate structure 120. In this arrangement, gate structure 120 is over SiC channels 108a, 108b and capping semiconductors 112a, 112b of each MOSFET 140a, 140b. Thus, gate structure 120 can simultaneously apply a voltage bias to each SiC channel 108a, 108b through gate dielectric layer 122 and any layers of capping semiconductor 112a, 112b to control source-drain conductivity through each MOSFET 140a, 140b thereunder.

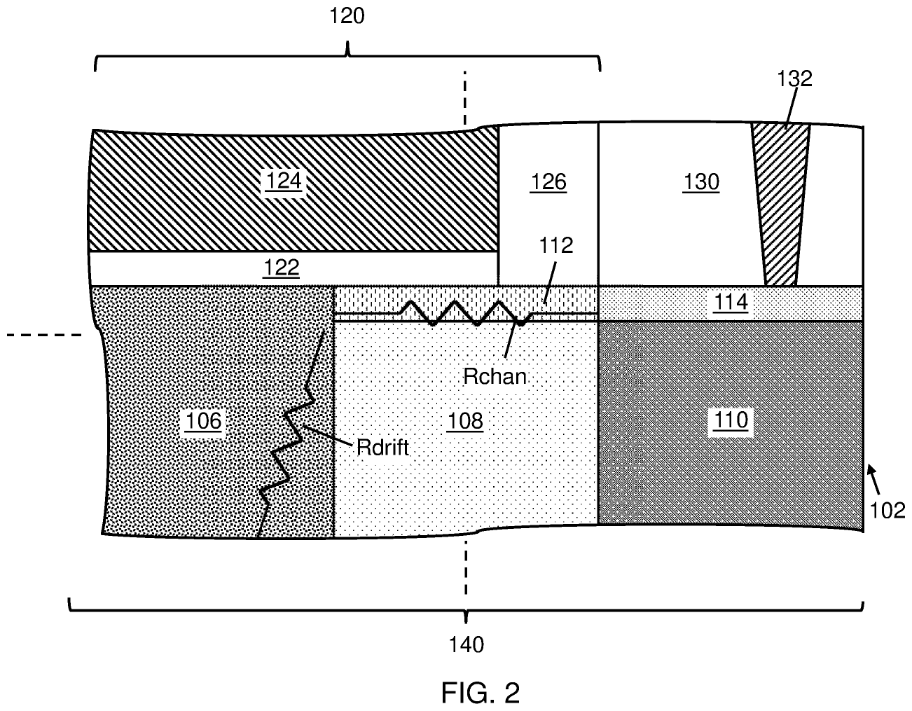

Referring to FIG. 2, an expanded view of MOSFET 140 is shown to further illustrate technical features and advantages of the disclosure. Some elements of structure 100 (FIG. 1) are omitted from the expanded view of MOSFET 140 solely for clarity of illustration. Although the orientation and position of MOSFET 140 and its components correspond to first MOSFET 140a of FIG. 1, the same characteristics apply to second MOSFET 140b (FIG. 1) and/or other MOSFETs according to embodiments of the disclosure. The boundaries with other material(s) within structure 100 are indicated with cutoff lines and dashed lead lines. The expanded view of first MOSFET 140 illustrates two sources of internal resistance, i.e., a channel resistance (“Rchan”) indicating the resistance between source 110 and drain drift region 106, and a drift resistance (“Rdrift”) indicating the resistance between drain drift region 106 and lower drift region 104 (FIG. 1).

It has been determined that in an electrical structure integrating MOSFET and JFET devices, nearly half of the total internal resistance arises within the MOSFET channel and a further twenty percent of the total internal resistance arises from the electrical coupling from MOSFET to JFET from drain region to drift region. The presence capping semiconductor 112 over SiC channel 108 mitigates these two sources of internal resistance. As discussed herein, capping semiconductor 112 is formed of a material having a higher charge carrier mobility than SiC channel 108, e.g., by being substantially or entirely free of SiC material therein. In turn, this creates a less resistive electrical pathway from source 110 to drain drift region 106 that is still subject to the electrical biasing from gate structure 120. Capping semiconductor 112, in addition to reducing Rchan, also provides unexpectedly beneficial reductions in Rdrift. Specifically, the presence of capping semiconductor 112 offsets the relatively low doping levels within lower drift region 104 (FIG. 1), and thus allows current to flow more freely through drain drift region 106. Capping semiconductor 112, during operation, will serve as a “counter doping region” relative to lower drift region 104 and thus will allow lower drift region 104 to accommodate higher magnitudes of current and voltage therein.

Turning to FIG. 3, a more detailed cross-sectional view of structure 100 is shown, including MOSFETs 140a, 140b and a vertical JFET structure 150 thereunder. A JFET structure, e.g., vertical JFET structure 150, operates by providing a pair of oppositely-doped semiconductor materials separated by a less conductive (or even non-conductive) region of semiconductor material. By applying voltages to one of the doped semiconductor materials, the non-conductive region may grow or shrink to affect passage of electricity through the other doped semiconductor material. In the case of vertical JFET structure 150, drain drift region 106 serves as a conductive semiconductor material, lower drift region 104 may be a less conductive semiconductor material beneath drain drift region 106, and a conductive buffer region 152 and drain terminal 154 (below buffer region 152) provide the other conductive semiconductor material. Electrical biasing of SiC channel(s) 108a, 108b will temporarily increase the conductivity through lower drift region 104, allowing conduction through vertical JFET structure 150 to drain drift region 106 of MOSFET(s) 140a, 140b, i.e., from drain terminal 154 to drain drift region 106 through lower drift region 104.

As shown, lower drift region 104 may be alongside SiC channel(s) 108a, 108b but also may extend below lower surfaces of each SiC channel(s) 108a, 108b. The presence of a corner junction 156 between these two materials exhibits high sensitivity to doping, which may affect the breakdown voltage of vertical JFET structure 150 (i.e., the highest voltage level at which vertical JFET structure 150 can operate). SiC may provide stronger biasing of lower drift region 104 than would otherwise be possible using crystalline semiconductor materials. Thus, the presence of capping semiconductor(s) 112 may allow SiC to be present in areas that are horizontally adjacent lower drift region 104. Embodiments of structure 100 thus allow SiC material(s) to be used where desirable in vertical JFET structure 150, while allowing a much smaller amount of higher charge carrier (non-SiC) material(s) to be used in the active components of each MOSFET 140a, 140b.

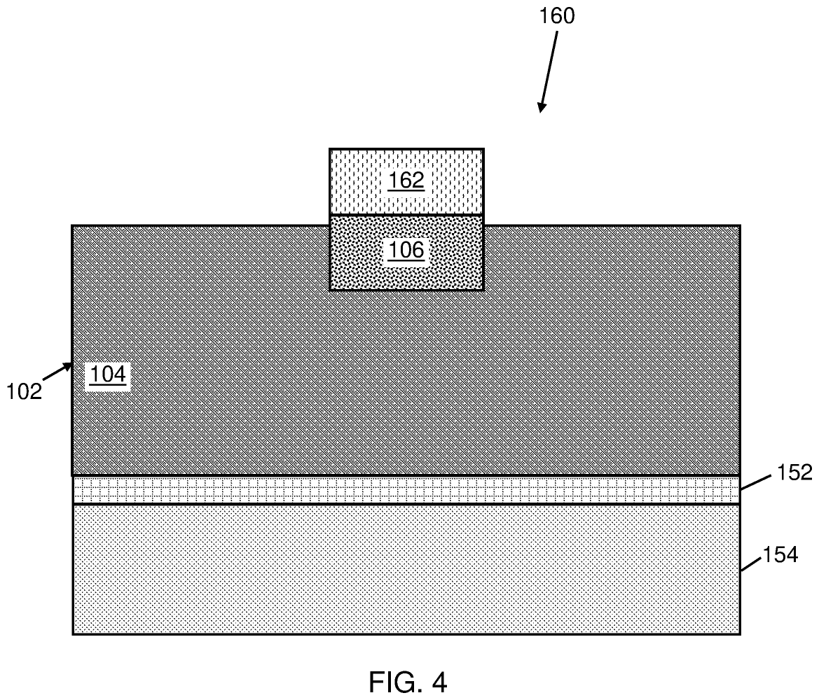

Referring to FIG. 4, illustrating a preliminary structure 160, the disclosure provides methods to form structure 100 (FIGS. 1, 3) as discussed herein. In preliminary structure 160, SiC substrate 102 may initially include lower drift region 104 (e.g., a lightly doped N-type region of SiC) on buffer region 152 (e.g., a layer of SiC that has the same doping type as lower drift region 104 in a higher concentration), and buffer region 152 may be on drain terminal 154 (e.g., a layer of SiC that has the same doping type as lower drift region 104 and buffer region 152 but in a higher concentration than either layer thereover). Drain drift region 106 may already be present within lower drift region 104, e.g., by forming additional N-type dopants within lower drift region 104 (e.g., by implantation). The forming of drain drift region 106 may be achieved by an earlier performed masking and doping (e.g., implantation) step as generally known in the art. A masking material 162 (e.g., an oxide or nitride mask, and/or other currently known or later developed masking materials) may be on drain drift region 106 to protect drain drift region 106 from further processing. Portions of lower drift region 104 not covered by masking material 162 may be partially recessed (e.g., by etching) such that an upper surface of drain drift region 106 is above an adjacent upper surface of lower drift region 104.

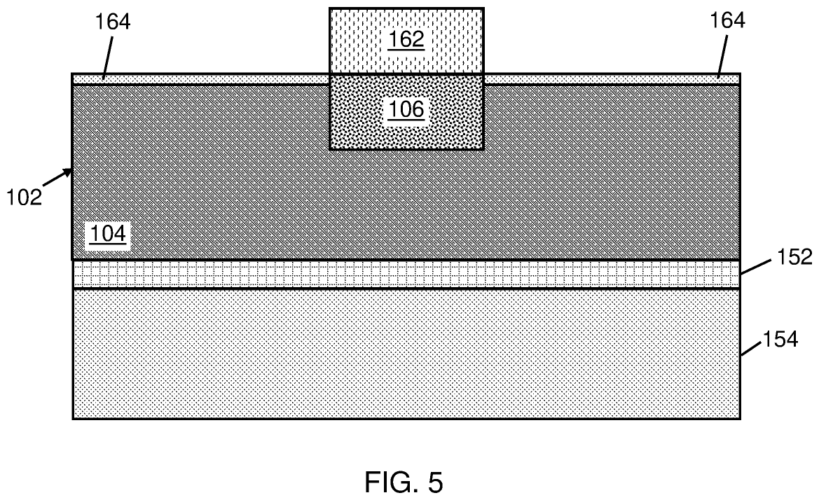

With masking material 162 in place, FIG. 5 depicts further processing to form an initial capping semiconductor 164 on lower drift region 104. The forming of initial capping semiconductor 164 may be implemented by epitaxial deposition, i.e., growing of crystalline semiconductor material(s) on lower drift region 104. Unlike the SiC material within lower drift region 104, initial capping semiconductor 164 may be free of SiC and thus may include crystalline Si. To preserve the crystallographic structure of initial capping semiconductor 164, the thickness of initial capping semiconductor may be controlled such its upper surface is approximately coplanar with the upper surface of drain drift region 106. According to one example, the vertical thickness of initial capping semiconductor 164 may be at most approximately ten nm. Initial capping semiconductor 164 may be free of doping, e.g., it may be formed such that an insignificant concentration of P-type or N-type dopants is within initial capping semiconductor 164 despite the N-type doping of lower drift region 104.

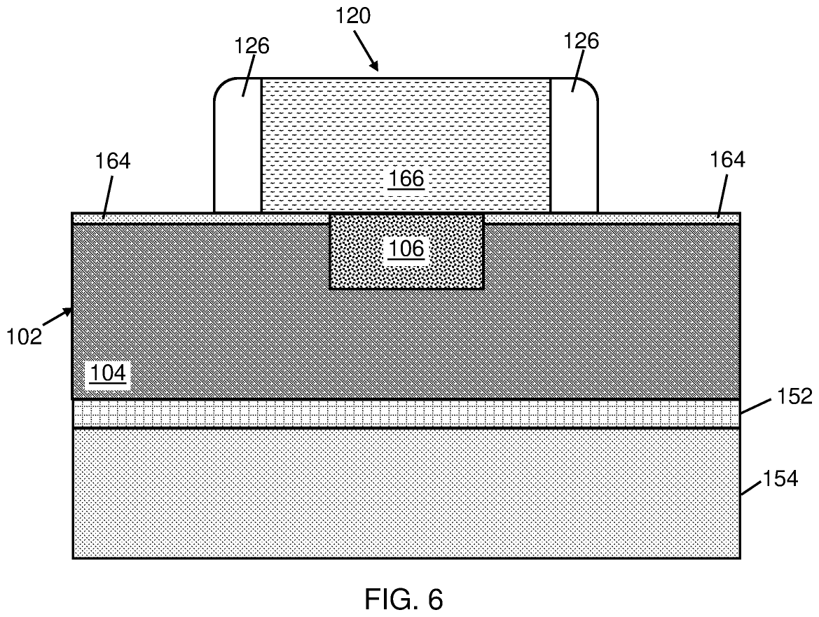

Continuing to FIG. 6, methods of the disclosure may include removing masking material 162 (FIGS. 4-6) to form gate structure 120, e.g., over portions of initial capping semiconductor(s) 164 and drain drift region 106. Gate structure 120 optionally may include the same components discussed elsewhere herein with regard to structure 100 (e.g., it may include gate dielectric layer 122 (FIGS. 1-3) and gate conductor(s) 124 (FIGS. 1-3). However, gate structure 120 alternatively may include a placeholder gate 166 (e.g., polycrystalline semiconductor(s)) above SiC substrate 102 and horizontally adjacent spacer(s) 126. Such material (when used) may be removed and replaced with functional gate components via replacement metal gate (RMG) processing as generally known in the art. Placeholder gate 166 thus is shown in gate structure 120 as an example, but gate dielectric layer 122 and/or gate conductor(s) 124 may be present in other embodiments. The forming of gate structure 120, in any case, may be implemented according to any currently known or later developed process to form a gate structure (e.g., deposition of placeholder gate 166 or gate dielectric layer 122 and gate conductor(s) 124), as well as forming of spacer(s) 126 on sidewall(s) of these materials. The forming of gate structure 120, however implemented, will cover some portions of initial capping semiconductor(s) 164 and drain drift region 106.

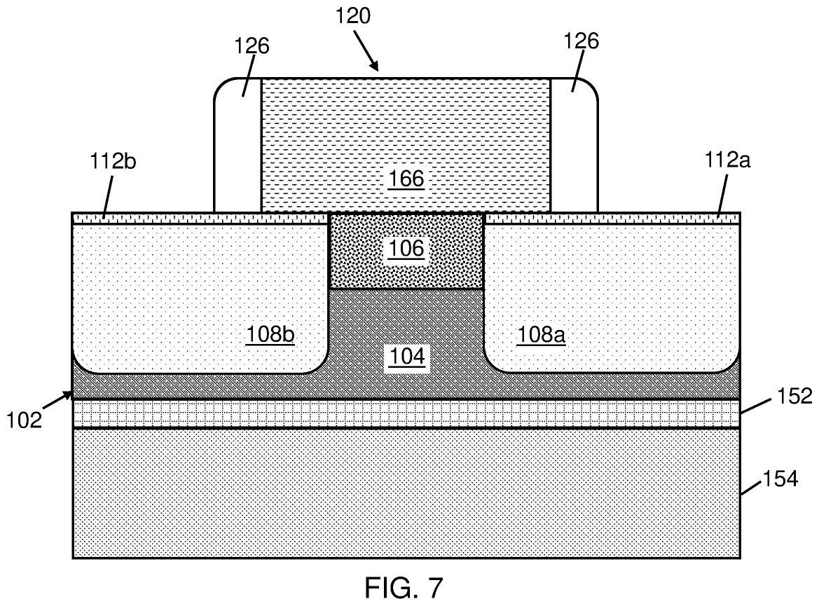

FIG. 7 depicts further processing to provide doping appropriate for active material(s) within MOSFET(s) 140 (FIGS. 1-3). Optionally with gate structure 120 in place, portions of lower drift region 104 and initial capping semiconductor 164 (FIG. 5) can be doped, e.g., by tilted implantation and/or any other currently known or later developed doping procedure to create doped regions within semiconductive material and below portions of gate structure 120. Some dopants may pass through initial capping semiconductor 164 to dope lower drift region 104, whereas other dopants may remain within initial capping semiconductor 164 to affect its doping profile. The doped portion(s) of lower drift region 104 thus may become SiC channel(s) 108 (separately illustrated as 108a, 108b) and may have an opposite doping polarity from lower drift region 104. For instance, SiC channel(s) 108 may be doped P-type in the case where lower drift region 104 is doped N-type or vice versa. SiC channel(s) 108 may extend to a predetermined depth within lower drift region 104, e.g., they may extend below drain drift region 106 but not to the upper surface of buffer region 152. The doping of material(s) not covered by masking material 162 also may convert initial capping semiconductor 164 into capping semiconductor(s) 112 (separately illustrated as 112a, 112b) over SiC channel(s) 108. Capping semiconductor(s) 112, as discussed herein, may be substantially or entirely free of SiC but may have the same doping type as SiC channel(s) 108 thereunder. For instance, capping semiconductor(s) 112 may be doped P-type in the case where lower drift region 104 is doped N-type or vice versa.

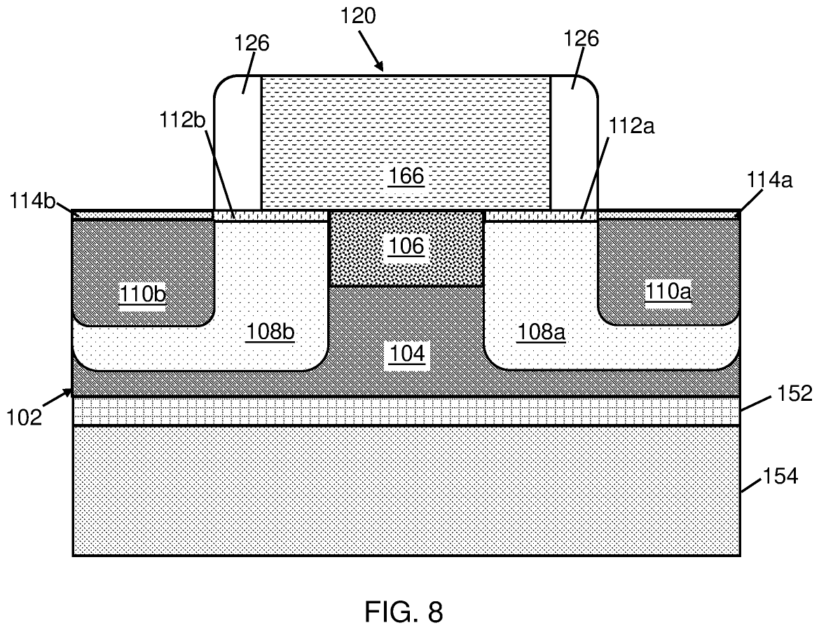

FIG. 8 depicts the forming of source(s) 110 (separately labeled 110a, 110b for reference), and optionally the forming of source capping semiconductor(s) 114 (separately labeled 114a, 114b for reference) thereover. The forming of source(s) 110 and/or source capping semiconductor(s) 114 may include, e.g., further doping in portions of SiC channel(s) 108 and/or capping semiconductor(s) 112 that are not covered by gate structure 120. This further doping (e.g., by implantation and/or other currently known or later developed doping techniques) may use ions having an opposite doping type from those used to from SiC channel(s) 108 and capping semiconductor(s) 112, i.e., they may be N-type in the case where SiC channel(s) 108 and capping semiconductor(s) 112 are doped P-type or vice versa. The doping of SiC channel(s) 108 may be controlled such that the lower surface of source(s) 110 is above the lower surface of SiC channel 108, i.e., source(s) 110 do not extend into and/or otherwise interface with lower drift region 104. Similarly capping semiconductor(s) 112 and source capping semiconductor(s) 114 may retain the same vertical thickness as initial capping semiconductor 164 (FIG. 5), regardless of how they are doped, due to the substantial or complete absence of SiC from these materials. Further processing may include, e.g., forming gate dielectric layer(s) 122 (FIGS. 1-3) and gate conductor(s) 124 (FIGS. 1-3) in gate structure 120, forming of ILD 130 (FIGS. 1-3) and contact(s) 132a, 132b, 134 (FIGS. 1-3) through any currently known or later developed MOL processing scheme.

Embodiments of the disclosure provide various technical and commercial advantages, examples of which are discussed herein. The presence of capping semiconductor(s) 112 over SiC channel(s) 108 may preserve the technical benefits of using SiC material(s) in a MOSFET (e.g., for a power transistor structure), while providing a beneficial reduction in resistance within the MOSFET as well as interconnected JFETs in SiC substrate 102. These benefits are achievable without posing a risk of material defects within capping semiconductor(s) 112, e.g., due to the controllability of vertical size over SiC substrate 102. Embodiments of the disclosure also can be manufactured with few changes to conventional manufacturing techniques to form MOSFET and/or JFET transistors, e.g., only a single epitaxial deposition may produce initial capping semiconductor(s) 164 (FIG. 5) and existing doping processes may simultaneously dope this material to provide capping semiconductor(s) 112 and/or source capping semiconductor(s) 114.

The method and structure as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a center processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a silicon carbide (SiC) channel horizontally between a source and a drain drift region, wherein the SiC channel has opposite doping from the source and the drain drift region; and
a capping semiconductor on the SiC channel and horizontally between the source and the drain drift region, wherein the capping semiconductor includes a semiconductor having a higher charge carrier mobility than the SiC channel, and a gate structure is on the capping semiconductor.

2. The structure of claim 1, wherein the capping semiconductor comprises crystalline silicon (Si).

3. The structure of claim 1, wherein the drain drift region is within a vertical junction field effect transistor (JFET) structure having a drain terminal below the drain drift region.

4. The structure of claim 3, wherein a portion of the drift region extends below the SiC channel such that a lower surface of the SiC channel interfaces with an upper surface of the drift region.

5. The structure of claim 1, wherein the capping semiconductor is vertically interposed between the SiC channel and the gate structure.

6. The structure of claim 1, wherein the source includes the capping semiconductor thereon, and the drain drift region is free of the capping semiconductor.

7. The structure of claim 1, wherein a vertical thickness of the capping semiconductor is at most approximately ten nanometers (nm).

8. A structure comprising:
a silicon carbide (SiC) substrate including:
a drain drift region having a first doping type and included within a vertical junction field effect transistor (JFET),
a first channel having a second doping type and horizontally adjacent a first end of the drain drift region, and
a first source having the first doping type and horizontally adjacent the first channel, wherein the first channel is horizontally between the drain drift region and the first source,
a gate structure over the first channel of the SiC substrate; and
a capping semiconductor on the first channel and horizontally between the first source and the drain drift region, wherein the capping semiconductor includes a semiconductor having a higher charge carrier mobility than SiC, and the capping semiconductor is vertically interposed between the first channel and the gate structure.

9. The structure of claim 8, wherein the capping semiconductor is free of carbon (C) and comprises crystalline silicon (Si).

10. The structure of claim 8, wherein a portion of the drift region extends below the SiC channel such that a lower surface of the SiC channel interfaces with an upper surface of the drift region.

11. The structure of claim 8, wherein the capping semiconductor structurally isolates the gate structure from first channel.

12. The structure of claim 8, wherein a vertical thickness of the capping semiconductor is at most approximately ten nanometers (nm).

13. The structure of claim 8, wherein the SiC substrate further includes:
a second channel having the second doping type and horizontally adjacent a second end of the drain drift region opposite the first end; and
a second source having the first doping type horizontally adjacent the second channel such that the second channel is horizontally between the drain drift region and the second source.

14. The structure of claim 13, wherein the gate structure extends horizontally over the first source, the first channel, the drain drift region, the second channel and the second source.

15. The structure of claim 8, wherein the vertical JFET further includes:
a lower drift region below the drain drift region;
a semiconductor buffer region below the lower drift region; and
a drain terminal below the semiconductor buffer region such that the semiconductor buffer region separates the drain terminal from the drain, the first channel, and the first source.

16. A method comprising:
forming a silicon carbide (SiC) substrate including a channel horizontally between a source and a drain drift region, wherein the channel has opposite doping from the source and the drain drift region; and
forming a capping semiconductor on the SiC channel and horizontally between the source and the drain drift region, wherein the capping semiconductor includes a semiconductor having a higher charge carrier mobility than the SiC channel.

17. The method of claim 16, wherein the capping semiconductor comprises crystalline silicon (Si).

18. The method of claim 16, further comprising forming a gate structure over the SiC channel, wherein forming the gate structure vertically interposes the capping semiconductor between the capping semiconductor and the gate structure.

19. The method of claim 16, wherein forming the SiC substrate further includes forming an additional channel adjacent the drain drift region and an additional source adjacent the additional channel, such that the drain drift region is horizontally between the channel and the additional channel.

20. The method of claim 16, wherein a vertical thickness of the capping semiconductor is at most approximately ten nanometers (nm).
